(19) United States
(12) Patent Application Publication
(10) Pub. No.: US 2024/0079508 A1
(43) Pub. Date: Mar. 7, 2024

(54) Pyrolysis Apparatus for Completely Separating EVA Crystal Silicon Wafer from Waste Photovoltaic Module

(71) Applicant: CHANGZHOU INSTITUTE OF TECHNOLOGY, Changzhou (CN)

(72) Inventors: Quanfa ZHOU, Changzhou (CN); Jingbo ZHAO, Changzhou (CN); Xiaohui CHEN, Changzhou (CN); Pin ZHOU, Changzhou (CN); Shubo WANG, Changzhou (CN); Xueyuan JIN, Changzhou (CN)

(73) Assignee: CHANGZHOU INSTITUTE OF TECHNOLOGY, Changzhou (CN)

(21) Appl. No.: 18/218,590

(22) Filed: Jul. 6, 2023

(30) Foreign Application Priority Data
Sep. 1, 2022 (CN) 202211062448.7

(51) Int. Cl. H01L 31/0224; B09B 3/40

(52) U.S. Cl. CPC H01L 31/022441; B09B 3/40; B09B 2101/15

(57) ABSTRACT

A pyrolysis apparatus for completely separating an EVA crystal silicon wafer from a waste photovoltaic module includes a heating mechanism controlled by a control system and mounted in a pyrolysis box and being capable of performing telescopic motion in a vertical direction; an overturning assembly for fixedly clamping and driving a photovoltaic module to overturn, the overturning assembly is arranged just under the heating mechanism; and a splitting assembly for separating the photovoltaic module, the splitting assembly is arranged at a left side of the photovoltaic module fixedly clamped by the overturning assembly. A splitting apparatus is provided for assisting in splitting EVA, and isolating glass from the crystal silicon wafer, as well as isolating a back plate from the crystal silicon wafer, and therefore, the pressure generated on the crystal silicon wafer due to large strength of the glass and shrinkage of the back plate is prevented.

### CROSS REFERENCE TO THE RELATED APPLICATIONS

This application is based upon and claims priority to Chinese Patent Application No. 202211062448.7, filed on Sep. 1, 2022, the entire contents of which are incorporated herein by reference.

### TECHNICAL FIELD

The present disclosure relates to the technical field of photovoltaic module recovery, and particularly relates to a pyrolysis apparatus for completely separating an EVA crystal silicon wafer from a waste photovoltaic module.

### BACKGROUND

In recent years, with the continuous development of global economy, the energy consumption is increasing, and traditional fossil energy sources are increasingly depleted and cause environmental pollution. Therefore, solar energy has received unprecedented attention as a clean energy. Although China start solar energy industry quite late, but has made rapid development, and now takes the worldwide lead in the solar energy industry. It is predicted that the national photovoltaic cumulative installed capacity will reach 250 GW in 2020. Photovoltaic modules are designed to generate clean and renewable energy without polluting the environment, and have service lives of up to 30 years. Up to now, the 1st generation of photovoltaic modules developed at the end of the 20th century have been discarded. According to professional estimation, the discarded photovoltaic modules will break through 1000 t by 2020, and up to 1957099 t by 2038. If the photovoltaic modules cannot be reasonably and efficiently recycled, serious environmental problems and resource waste will be caused. Therefore, full recycling of glass, precious metals, silicon wafers and the like in the waste photovoltaic modules has very important economic and environmental protection significance.

Crystalline silicon photovoltaic modules account for 80% or above of all photovoltaic modules produced globally, and their main components include surface glass, packaging materials, silicon wafers, back plates and metal belts. The surface tempered glass is used for receiving light irradiation and enhancing the mechanical strength, durability and optical transparency of the modules. Generally, an ethylene-vinyl acetate copolymer (EVA) with excellent moisture resistance is selected as the packaging material, and the EVA shows good adhesive performance in a glass sealant/back plate structure.

At present, there already have some methods for recycling the crystalline silicon photovoltaic modules abroad, mainly including a solvent method and a heat treatment method.

In practical application, the solvent dissolution method has the defects of large solvent consumption, low dissolution rate, long dissolution time, difficult waste liquid treatment and the like, so it can only be applied on a small scale. The heat treatment method is a method for softening, stripping or decomposing an organic encapsulation layer EVA under a heating condition to achieve the purpose of separating cover plate glass and a solar cell. The pyrolysis method also has certain defects, for example, in the pyrolysis process, local overheating is easy to occur due to uneven heating, so as to cause breakage of a cell piece, thus the integrity of a silicon cell cannot be kept, and moreover, a very small amount of organic matter may be left on the surface of the cell after pyrolysis to affect the product purity. In addition, during pyrolysis, the pressure between the glass and the crystal silicon wafer is increased due to continuous temperature increase, and the back plate will shrink during heating to generate stress which causes breakage of the crystal silicon wafer, and as a result, the complete crystal silicon wafer cannot be recovered.

Therefore, a pyrolysis apparatus for completely separating an EVA crystal silicon wafer from a waste photovoltaic module is provided to solve the above problems.

### SUMMARY

An objective of the present disclosure is to provide a pyrolysis apparatus for completely separating an EVA crystal silicon wafer from a waste photovoltaic module to solve the defects in the prior art that during pyrolysis, the pressure between glass and a crystal silicon wafer is increased due to continuous temperature increase, and a back plate will shrink during heating to generate stress which causes breakage of the crystal silicon wafer, and as a result, the complete crystal silicon wafer cannot be recovered.

In order to achieve the above objective, the present disclosure adopts the following technical solution:

A pyrolysis apparatus for completely separating an EVA crystal silicon wafer from a waste photovoltaic module, which includes a heating mechanism controlled by a control system and mounted in a pyrolysis box and being capable of performing telescopic motion in a vertical direction;
an overturning assembly for fixedly clamping and driving a photovoltaic module to overturn, the overturning assembly is arranged just under the heating mechanism; and
a splitting assembly for separating the photovoltaic module, the splitting assembly is arranged at a left side of the photovoltaic module fixedly clamped by the overturning assembly, and a cutting knife of the splitting assembly and a middle part of an EVA of the photovoltaic module are on a same horizontal plane.

Preferably, the heating mechanism includes a distribution box fixed in the pyrolysis box, a mounting frame fixed above the distribution box, an air inlet pipe fixed between the mounting frame and the distribution box, a hose fixedly connected to the air inlet pipe, a hot air pipe fixedly connected to the hose, and an air heater fixedly connected to an inlet end of the hot air pipe.

Preferably, two hydraulic push cylinders connected in series are fixed at an outer top of the pyrolysis box, and bottoms of the hydraulic push cylinders extend and are fixed to the mounting frame; a laser sensor is fixed at one end of the mounting frame, and the hydraulic push cylinders are controlled to perform shrinkage motion to drive the mounting frame and the distribution box to synchronously move upwards, and the hose shrinks accordingly, thus the position of the distribution box can be adjusted from a state shown in FIG. 1 to a state shown in FIG. 3.

Preferably, a plurality of distribution holes are formed in the bottom of the distribution box, the transversely arranged distribution holes and the vertically arranged distribution holes are spaced at equal intervals, and nozzles are fixed in the distribution holes through threads.

Specifically, the start of the air heater is controlled by the control system, and the heating temperature of the air heater is controlled by an intelligent temperature controller in an auxiliary way; after a switch is turned on, the heated air flows to the hose through the hot air pipe, flows into the air inlet pipe through the hose, and then flows into the distribution box through the air inlet pipe; and the hot air is sprayed out through the nozzles in the bottom of the distribution box, and is vertically sprayed on an upper surface of the photovoltaic module.

Preferably, the overturning assembly includes a left clamping plate and a right clamping plate for clamping the photovoltaic module, an electric push rod fixedly connected to the right clamping plate, and an overturning motor fixedly connected to the left clamping plate; the overturning motor is fixed outside the pyrolysis box; and a left fixed pad and a right fixed pad are correspondingly fixed to side walls, close to each other, of the left clamping plate and the right clamping plate.

Preferably, the electric push rod is fixed to a push rod seat, and the electric push rod is also fixed to an inner ring of a bearing; the bearing is fixed in a mounting hole formed in the pyrolysis box; a displacement sensor is also fixed at a front end of the push rod seat; and a detection probe of the displacement sensor is inserted into the right clamping plate.

Specifically, when the electric push rod performs stretching motion, the detection probe of the displacement sensor is inserted into the right clamping plate, thus a motion state of the right clamping plate can be detected by the displacement sensor (the displacement sensor is also called as a linear sensor and belongs a metal inductive linear device, and the sensor is used for converting various measured physical quantities into electric quantity); and the right clamping plate is driven by the electric push rod to move, thus for a moving distance of the right clamping plate, an initial position and a termination position of the right clamping plate can be set in the control system according to the specification and size of the photovoltaic module (the length of the right fixed pad should also be considered), so as to obtain a moving distance of the displacement sensor after receiving a position signal of the displacement sensor, and if the moving distance of the displacement sensor is equal to a set distance by which the right clamping plate needs be moved, the electric push rod is controlled by the control system to stop the stretching motion.

Preferably, the splitting assembly includes a cutting knife inserted into a limiting frame, a fixed knife rest fixedly connected to one end of the cutting knife, a fixed sleeve fixedly connected to one end of the fixed knife rest, a nut pair mounted in the fixed sleeve, and a ball screw driven by a screw motor to drive the nut pair to perform linear motion; one end of the ball screw is fixed to a fixed block; and one end of the fixed block is connected to the limiting frame while the other end is fixed to an inner wall of the pyrolysis box.

Specifically, after the position of the photovoltaic module is fixed, the screw motor can be controlled by the control system to rotate forwards, the screw motor drives the ball screw to rotate, and then the nut pair is controlled to perform linear motion along the ball screw; due to the fact that the nut pair is fixedly mounted in the fixed sleeve, the fixed knife rest fixedly connected to the cutting knife is driven to move under the connection of the fixed sleeve, and the cutting knife is made to perform linear motion along the limiting frame and move toward the side where the photovoltaic module is positioned, thus realizing splitting treatment on the EVA between glass and the crystal silicon wafer.

Preferably, the control system is electrically connected to a power supply module, an intelligent temperature controller is arranged in the control system, the intelligent temperature controller is electrically connected to the air heater, the control system is further electrically connected to the screw motor, the overturning motor, the electric push rod and the hydraulic push cylinders, and signals detected by the laser sensor and the displacement sensor are transmitted to the control system.

Specifically, a control operation box of the control system is mounted outside the pyrolysis box, thus the operation of the pyrolysis box is convenient to control; and the control system is capable of controlling the screw motor, the overturning motor, the electric push rod and the hydraulic push cylinders mounted on the pyrolysis box according to operation requirements.

The present disclosure has the following beneficial effects:
1. In the present disclosure, the temperature is increased to the highest temperature at a fixed rate of 10° C./min and is maintained for 45 min during the pyrolysis process, thus an EVA packaging material can be removed, an EVA polymer can be completely decomposed, and no solid residue exists.
2. In the present disclosure, by virtue of mutual cooperation of the left clamping plate in a fixed state and the right clamping plate in a movable state, the photovoltaic module is stably clamped, and the photovoltaic module is fixed with the assistance of a clamp during pyrolysis, so that the good integrity of the crystal silicon wafer can be guaranteed.
3. In the present disclosure, a splitting apparatus is provided for assisting in splitting EVA, and isolating the glass from the crystal silicon wafer, as well as isolating the back plate from the crystal silicon wafer, and therefore, the pressure generated on the crystal silicon wafer due to large strength of the glass and shrinkage of the back plate is prevented; and the cutting knife plays an effect of isolating and protecting the crystal silicon wafer, thus the integrity of the crystal silicon wafer can be ensured during the pyrolysis process, and the crystal silicon wafer with favorable integrity is obtained.

### BRIEF DESCRIPTION OF THE DRAWINGS

FIG. 1 is a schematic forward-looking internal structure diagram of a pyrolysis apparatus for completely separating an EVA crystal silicon wafer from a waste photovoltaic module provided by the present disclosure;

FIG. 2 is a schematic overlooking internal structure diagram of a pyrolysis apparatus for completely separating an EVA crystal silicon wafer from a waste photovoltaic module provided by the present disclosure;

FIG. 3 is a schematic forward-looking structure diagram of a pyrolysis apparatus for completely separating an EVA crystal silicon wafer from a waste photovoltaic module in an overturning state provided by the present disclosure;

FIG. 4 is a schematic upward-looking structure diagram of positions of nozzles in a bottom of a distribution box of a pyrolysis apparatus for completely separating an EVA crystal silicon wafer from a waste photovoltaic module provided by the present disclosure;

FIG. 5 is a schematic overlooking structure diagram of a mounting frame and a hose of a pyrolysis apparatus for completely separating an EVA crystal silicon wafer from a waste photovoltaic module provided by the present disclosure;

FIG. 6 is a schematic overlooking structure diagram of a pyrolysis apparatus for completely separating an EVA crystal silicon wafer from a waste photovoltaic module provided by the present disclosure;

FIG. 7 is a schematic left-looking structure diagram of a pyrolysis apparatus for completely separating an EVA crystal silicon wafer from a waste photovoltaic module provided by the present disclosure;

FIG. 8 is a schematic left-side direction structure diagram of a cutting knife and a photovoltaic module of a pyrolysis apparatus for completely separating an EVA crystal silicon wafer from a waste photovoltaic module provided by the present disclosure;

FIG. 9 is a schematic state structure diagram of a cutting knife in FIG. 8 moving into a photovoltaic module of a pyrolysis apparatus for completely separating an EVA crystal silicon wafer from a waste photovoltaic module provided by the present disclosure;

FIG. 10 is a schematic forward-looking diagram of a pyrolysis apparatus for completely separating an EVA crystal silicon wafer from a waste photovoltaic module provided by the present disclosure;

FIG. 11 is a schematic system module diagram of a pyrolysis apparatus for completely separating an EVA crystal silicon wafer from a waste photovoltaic module provided by the present disclosure; and

FIG. 12 is an EVA thermal gravity (TG) and differential thermal gravity (DTG) curve of a pyrolysis apparatus for completely separating an EVA crystal silicon wafer from a waste photovoltaic module in an air atmosphere provided by the present disclosure.

In figures: 1, pyrolysis box; 2, hydraulic push cylinder; 3, push cylinder seat; 4, heating mechanism; 5, overturning assembly; 6, displacement sensor; 7, photovoltaic module; 8, splitting assembly; 9, box door; 10, laser sensor;
41, hose, 42, air inlet pipe; 43, distribution box; 44, nozzle; 45, mounting frame; 46, air heater; 47, hot air pipe; 48, switch; 51, electric push rod; 52, push rod seat; 53, right clamping plate; 54, overturning motor; 55, right fixed pad; 56, left fixed pad; 57, left clamping plate; 81, limiting frame; 82, cutting knife; 83, fixed knife rest; 84, screw motor; 85, fixed sleeve; 86, nut pair; 87, ball screw; and 88, fixed block.

### DETAILED DESCRIPTION OF THE EMBODIMENTS

The technical solutions in the embodiments of the present disclosure will be clearly and completely described in conjunction with the accompanying drawings in the embodiments of the present disclosure, and obviously, the described embodiments are only a part of the embodiments of the present disclosure, but not all the embodiments.

The contents not described in detail in the specification belongs to the prior art known to those skilled in the art.

All standard parts used in the present disclosure can be purchased from the market, special-shaped parts can be customized according to the description of the specification and the accompanying drawings, the specific connection mode of each part adopts mature conventional means such as connecting by bolts, rivets and welding in the prior art; the machinery, parts and devices all adopt conventional models in the prior art; and the circuit connection adopts conventional connection modes in the prior art, which are not described in detail herein.

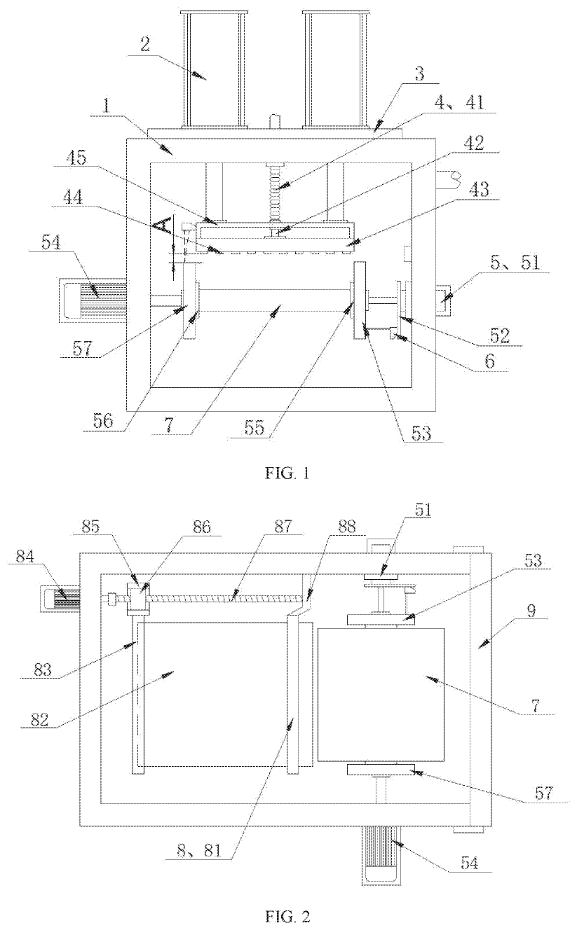

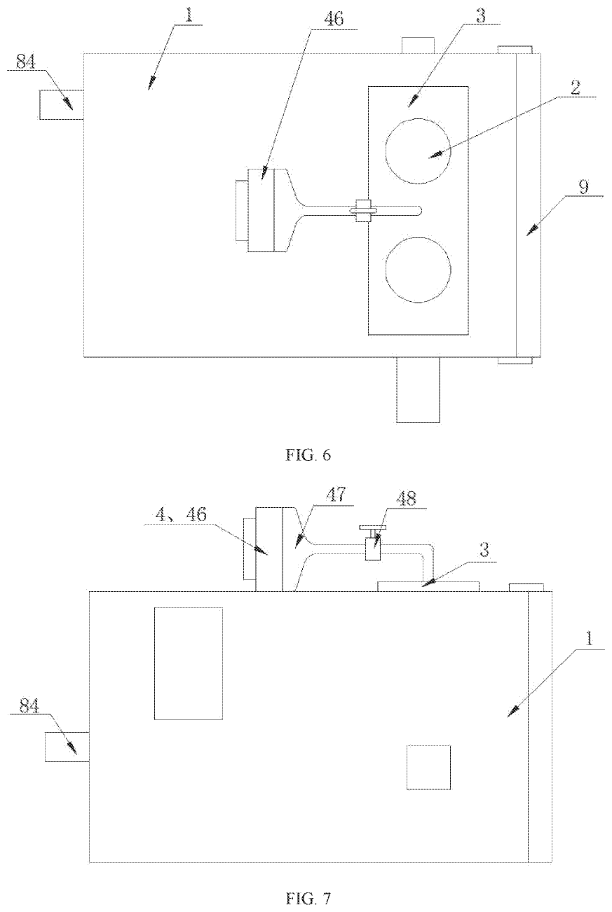

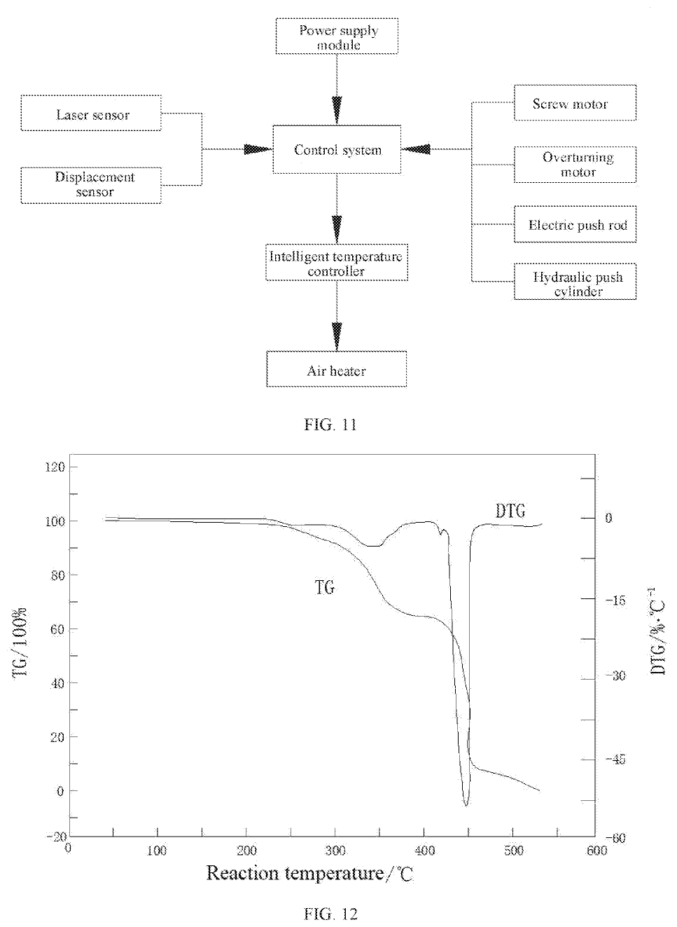

Embodiment: referring to FIG. 1 to FIG. 12, a pyrolysis apparatus for completely separating an EVA crystal silicon wafer from a waste photovoltaic module includes a heating mechanism 4 controlled by a control system and mounted in a pyrolysis box 1 and being capable of performing telescopic motion in a vertical direction; the control system is electrically connected to a power supply module, and the power supply module is used for supplying power to the control system and other devices of the pyrolysis box 1; an intelligent temperature controller is arranged in the control system, and the intelligent temperature controller is electrically connected to an air heater 46; the intelligent temperature controller is a YUDIAN AI-708P programmed artificial intelligence temperature controller/PID regulator, which has the 30+20-section program control function and can achieve the temperature increasing and decreasing control function at any slope, and therefore the air heater 46 controlled by the temperature controller can be arranged through the setting of the temperature controller; the temperature is increased at a fixed temperature rising rate to reach the highest temperature and maintained for 45 min, thus EVAs on two sides of the crystal silicon wafer can be removed, and the crystal silicon wafer and a glass sheet can be completely separated from a back plate; and waste gas generated in the pyrolysis process can be exhausted through a waste gas pipe connected to the pyrolysis box 1 and subjected to environment-friendly harmless retreatment.

The control system is further electrically connected to a screw motor 84, an overturning motor 54, an electric push rod 51 and hydraulic push cylinders 2; signals detected by a laser sensor 10 and a displacement sensor 6 are transmitted to the control system; a control operation box of the control system is mounted outside the pyrolysis box 1, thus the operation of the pyrolysis box 1 is convenient to control; and the control system is capable of controlling the screw motor 84, the overturning motor 54, the electric push rod 51 and the hydraulic push cylinders 2 mounted on the pyrolysis box 1 according to operation requirements.

As shown in FIG. 1 and FIG. 3 to FIG. 7 in the accompanying drawings of the specification, the heating mechanism 4 includes a distribution box 43 fixed in the pyrolysis box 1, a mounting frame 45 fixed above the distribution box 43, an air inlet pipe 42 fixed between the mounting frame 45 and the distribution box 43, a hose 41 fixedly connected to the air inlet pipe 42, a hot air pipe 47 fixedly connected to the hose 41, and the air heater 46 fixedly connected to an inlet end of the hot air pipe 47.

Two hydraulic push cylinders 2 connected in series are fixed at an outer top of the pyrolysis box 1; bottoms of the hydraulic push cylinders 2 extend and are fixed to the mounting frame 45; and the laser sensor 10 is also fixed at one end of the mounting frame 45.

Specifically, the control system is controlled to run through the operation box, the start of the air heater is controlled by the control system, and the heating temperature of the air heater 46 is controlled by the intelligent temperature controller in an auxiliary way; and after a switch 48 is turned on, the heated air flows to the hose 41 through the hot air pipe 47, flows into the air inlet pipe 42 through the hose 41, and then flows into the distribution box 43 through the air inlet pipe 42; and the hot air is sprayed out through nozzles 44 in the bottom of the distribution box 43, and is vertically sprayed on an upper surface of the photovoltaic module 7.

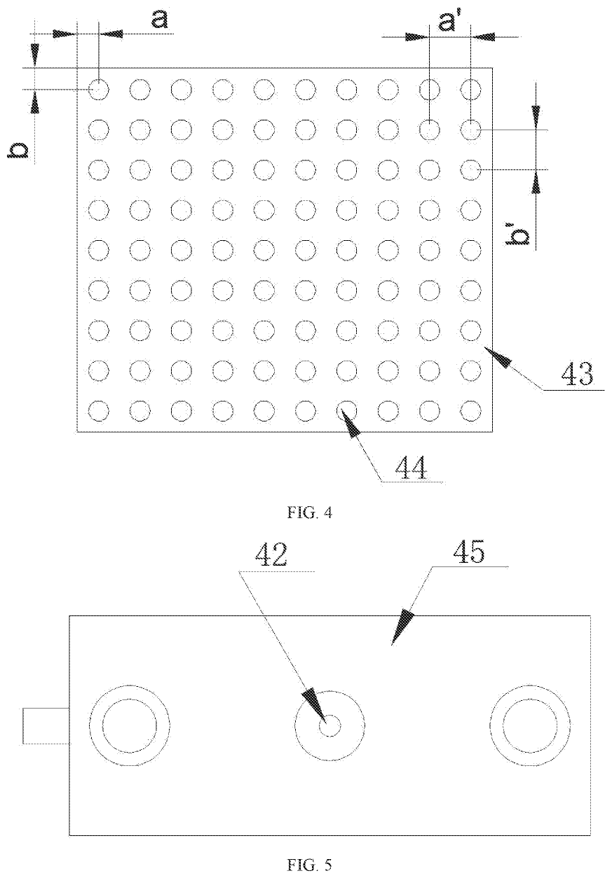

A plurality of distribution holes are formed in the bottom of the distribution box 43; as shown in FIG. 4 in the accompanying drawings of the specification, the distance of a section a is equal to the distance of a section b, and the distance of a section a′ is equal to the distance of a section b′, i.e., the transversely arranged distribution holes and the vertically arranged distribution holes are spaced at equal intervals; the nozzles 44 are fixed in the distribution holes through threads, and therefore, when the nozzles 44 spray hot air to the upper surface of the photovoltaic module 7, the hot air is uniformly sprayed; the hot air with the same temperature can be sprayed to the upper surface of the photovoltaic module 7 by the same height (the distance of a section A in FIG. 1), thus the heating uniformity of the photovoltaic module 7 in the pyrolysis treatment process is ensured, and the problems that the crystal silicon wafer is broken due to uneven heating and local overheating and the integrity of a silicon cell cannot be kept are solved.

When the photovoltaic module 7 is pyrolyzed in the pyrolysis box 1, the pyrolysis temperature is set through the intelligent controller, and the temperature is increased at a rate of 10° C./min; the decomposition of the EVA in an air atmosphere is divided into two phases: 1, the temperature is 260-400° C. and the weight loss ratio is about 25%, when the temperature is 350° C., the maximum differential weight loss ratio is 5.43%, and this phase is mainly characterized in that an ester bond of the ethylene-vinyl acetate copolymer (EVA) is broken to release acetic acid and generate gas mixtures of CO2, CH and the like; and 2, the temperature in the phase 2 is 420-500° C., an EVA sample is rapidly decomposed at this phase, the weight loss ratio is about 75%, and when the temperature is greater than 525° C., the EVA polymer is completely decomposed and no solid residues exist; and an EVA TG and DTG curve in the air atmosphere can be measured through a Diamond TG thermal analyzer (the sensitivity is 0.2 ug, the temperature increasing rate is 0.01-100 C·min⁻¹ and the gas flow speed is 0-1000 mL·min⁻¹) by referring to FIG. 12 in the accompanying drawings of the specification.

As shown in FIG. 1 to FIG. 2 in the accompanying drawings of the specification, an overturning assembly 5 for fixedly clamping and driving the photovoltaic module 7 to overturn is provided; the overturning assembly 5 is arranged just under the heating mechanism 4; the overturning assembly 5 includes a left clamping plate 57 and a right clamping plate 53 for clamping the photovoltaic module 7, an electric push rod 51 fixedly connected to the right clamping plate 53, and an overturning motor 54 fixedly connected to the left clamping plate 57; the overturning motor 54 is fixed outside the pyrolysis box 1; a left fixed pad 56 and a right fixed pad 55 are correspondingly fixed to side walls, close to each other, of the left clamping plate 57 and the right clamping plate 53; the electric push rod 51 is fixed to a push rod seat 52, and the electric push rod 51 is also fixed to an inner ring of a bearing; the bearing is fixed in a mounting hole formed in the pyrolysis box 1; the displacement sensor 6 is also fixed at a front end of the push rod seat 52; and a detection probe of the displacement sensor 6 is inserted into the right clamping plate 53.

Specifically, after a box door 9 is opened, the photovoltaic module 7 to be subjected to pyrolysis treatment is fixed between the left clamping plate 57 and the right clamping plate 53, and the left fixed pad 56 and the right fixed pad 55 which are fixed to the left clamping plate 57 and the right clamping plate 53 are capable of performing padding receiving protection on the photovoltaic module 7; the left fixed pad 56 and the right fixed pad 55 (the fixed pads can be made of polyvinyl chloride (PVC) materials) can be marked according to the position of a cutting knife 82, thus after the position of the photovoltaic module 7 is clamped and fixed, one end of the cutting knife 82 and the middle part of the EVA of the photovoltaic module 7 are on a same horizontal plane; and in the pyrolysis process, after the EVA is cut by a splitting assembly 8 in an auxiliary mode, preliminary separation of glass and the crystal silicon wafer is realized.

The photovoltaic module 7 is arranged at the left clamping plate 57 in a fixed state, the electric push rod 51 is controlled by the control system to perform stretching motion, and the right clamping plate 53 is pushed by the electric push rod 51 to move toward the side where the photovoltaic module 7 is positioned; when the electric push rod 51 performs the stretching motion, the detection probe of the displacement sensor 6 is inserted into the right clamping plate 53, thus a motion state of the right clamping plate 53 can be detected by the displacement sensor 6 (the displacement sensor 6 is also called as a linear sensor and belongs to a metal inductive linear device, and the sensor is used for converting various measured physical quantities into electric quantity); the right clamping plate 53 is driven by the electric push rod 51 to move, thus for a moving distance of the right clamping plate 53, an initial position and a termination position of the right clamping plate 53 can be set in the control system according to the specification and size of the photovoltaic module 7 (the length of the right fixed pad 55 should also be considered), so as to obtain a moving distance of the displacement sensor 6 after receiving a position signal of the displacement sensor 6, and if the moving distance of the displacement sensor is equal to a set distance by which the right clamping plate 53 needs to be moved, the electric push rod 51 is controlled by the control system to stop the stretching motion, and therefore the photovoltaic module 7 can be stably clamped through mutual cooperation of the left clamping plate 57 in the fixed state and the right clamping plate 53 in a movable state.

After the upper layer EVA of the photovoltaic module 7 is splitted and pyrolyzed, the glass subjected to upper layer pyrolysis separation is taken out from the pyrolysis box 1; after the glass is taken out and while the photovoltaic module 7 is still clamped between the left clamping plate 57 and the right clamping plate 53, the photovoltaic module 7 can be controlled to perform 360° overturning motion under the driving of the overturning assembly 5, and thus the EVA on the other side of the crystal silicon wafer can be splitted and pyrolyzed.

When the overturning assembly 5 performs rotating motion, the start of the overturning motor 54 is controlled by the control system, the overturning motor 54 drives the left clamping plate 57 fixedly connected to the overturning motor under the action of a rotating shaft, the photovoltaic module 7 fixedly clamped between the left clamping plate 57 and the right clamping plate 53, the right clamping plate 53, the push rod seat 52 and the electric push rod 51 fixed to the inner ring of the bearing to perform following rotation, and thus the overturning motion of the photovoltaic module 7 is realized. The electric push rod 51 is mounted on the inner ring of the bearing, and the bearing is fixed to the pyrolysis box 1, so the inner ring of the bearing and the electric push rod 51 synchronously rotate in an outer ring of the bearing during rotation, and the bearing also plays a role in mounting and supporting.

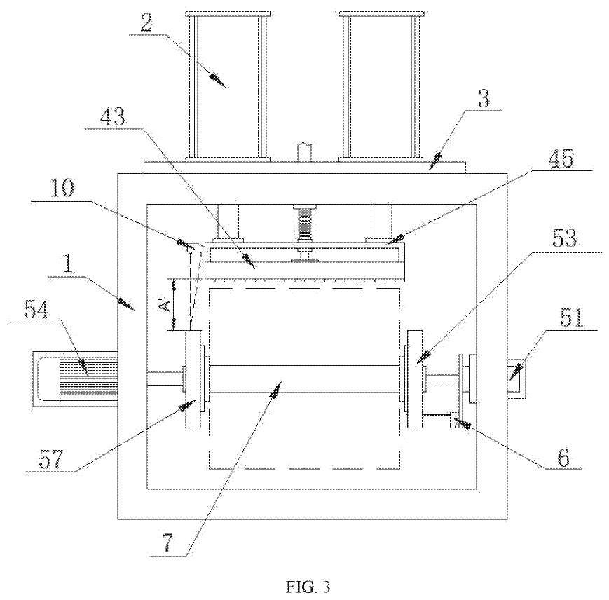

Before the overturning assembly 5 performs overturning, it is needed to control the hydraulic push cylinders 2 to perform shrinkage motion to drive the mounting frame 45 and the distribution box 43 to synchronously move upwards, and the hose 41 shrinks accordingly, thus the position of the distribution box 43 can be adjusted from a state shown in FIG. 1 to a state shown FIG. 3; a distance obtained after the distance of the section A in FIG. 1 and the distance of a section A′ in FIG. 3 are subtracted is the displacement of the distance, to be detected by the laser sensor 10, between the nozzle 44 and the corresponding clamping plate (the inside of the sensor is composed of a processor unit, an echo processing unit, a laser emitter, a laser receiver and the like; the laser sensor 10 is selected as a laser displacement sensor 6 which is a sensor for measuring through the laser technology and is composed of a laser device, a laser detector and a measuring circuit, and the sensor is capable of accurately measuring the change of the position, the displacement and the like of a measured object in a non-contact mode; the laser emitter emits visible red laser to the surface of the measured object through a lens, and the laser reflected by the object passes through a receiver lens and is received by an internal CCD linear camera; the CCD linear camera is capable of “viewing” the light spot at different angles according to different distances; and a digital signal processor can calculate the distance between the sensor and the measured object according to the angle and the known distance between the laser and the camera), thus, under the detection action of the laser sensor 10, the detected displacement data is transmitted to the control system, and the hydraulic push cylinders 2 are controlled to perform telescopic motion through the control system; after the photovoltaic module 7 is clamped, the hydraulic push cylinders 2 perform the stretching motion to drive the distribution box 43 and the nozzles 44 to move downwards from the position shown in FIG. 3 to the state shown in FIG. 1; after the photovoltaic module 7 is splitted and pyrolyzed and subjected to heat preservation for 45 min, and the glass is taken out, the hydraulic push cylinders 2 are controlled to perform shrinkage motion from the position shown in FIG. 1 to the position shown in FIG. 3, therefore the operation of the overturning assembly 5 can be controlled, and the photovoltaic module 7 can be driven to overturn.

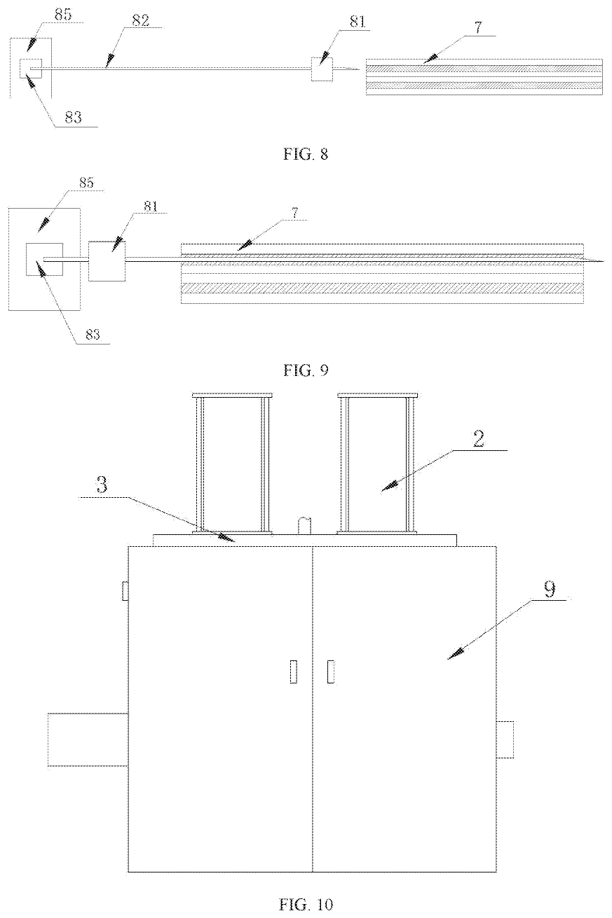

As shown in FIG. 2 and FIG. 8 in the accompanying drawings of the specification, the splitting assembly 8 for separating the photovoltaic module 7 is provided, and the splitting assembly 8 is arranged on a left side of the photovoltaic module 7 fixedly clamped by the overturning assembly 5, and the cutting knife 82 of the splitting assembly 8 and the middle part of EVA of the photovoltaic module 7 are on the same horizontal plane.

The splitting assembly 8 includes the cutting knife 82 inserted into a limiting frame 81, a fixed knife rest 83 fixedly connected to one end of the cutting knife 82, a fixed sleeve 85 fixedly connected to one end of the fixed knife rest 83, a nut pair 86 mounted in the fixed sleeve 85, and a ball screw 87 driven by the screw motor 84 to drive the nut pair 86 to perform linear motion; one end of the ball screw 87 is fixed to a fixed block 88, and one end of the fixed block 88 is connected to the limiting frame 81 while the other end is fixed to an inner wall of the pyrolysis box 1; the cutting knife 82 is inserted into the limiting frame 81 in a position fixed state, so the cutting knife 82 can transversely move in the limiting frame 81 when moving in a horizontal direction; the limiting frame 81 plays an auxiliary motion supporting role on the cutting knife 82, which ensures that the cutting knife 82 can keep overall balance during displacement, and the linear stability of the cutting knife 82 for splitting EVA in the follow-up process is guaranteed.

Specifically, after the position of the photovoltaic module 7 is fixed, the screw motor 84 can be controlled by the control system to rotate forwards, the screw motor 84 drives the ball screw 87 to rotate, and then the nut pair 86 is controlled to perform linear motion along the ball screw 87; and due to the fact that the nut pair 86 is fixedly mounted in the fixed sleeve 85, the fixed knife rest 83 fixedly connected to the cutting knife 82 is driven to move under the connection of the fixed sleeve 85, the cutting knife 82 is made to perform linear motion along the limiting frame 81 and move toward the side where the photovoltaic module 7 is positioned, thus realizing splitting treatment on the EVA between the glass and the crystal silicon wafer.

When the splitting assembly 8 is used for carrying out splitting treatment on the EVA, the nut pair 86 is driven to perform the linear motion through the ball screw 87, and the cutting knife 82 is driven to move to realize the splitting treatment; when the nut pair 86 moves, one end of the nut pair is limited through the fixed block 88 while the other end is limited through a coupler of the ball screw 87 and a motor rotating shaft, thus the nut pair 86 can be limited, and the situation that a nut is disengaged from a screw shaft in an overrun mode to cause falling off of balls is avoided. In addition, in the present application, the moving distance of the cutting knife 82 is equal to an effective stroke of the nut pair 86, i.e., the nut pair 86 starts to move from the initial position and drives the cutting knife 82 to move, and after the nut pair 86 moves to a top end of a screw, the cutting knife 82 completes the splitting to an EVA fan cover material at the same time.

As shown in FIG. 9 in the accompanying drawings of the specification, after EVA is splitted by the cutting knife 82, the cutting knife 82 can stay at the position shown in FIG. 9, and the nut pair 86 abuts against the fixed block 88 at the same time, therefore, according to the moving stroke of the nut pair 86, it is needed to control the screw motor 84 to stop: after the pyrolysis work is finished, the screw motor 84 can be controlled to rotate reversely, and the ball screw 87 is driven to rotate reversely to drive the cutting knife 82 to perform return motion.

Further, the splitting assembly 8 in the present application is matched with the heating mechanism 4 to run; in the running starting process of the heating mechanism 4, the temperature is increased at a rate of 10° C./min, and it is needed to increase the temperature to 500° C.; when the temperature is increased to 200° C., the splitting assembly 8 is controlled to run, i.e., in the process that the EVA of the photovoltaic module 7 is continuously pyrolyzed, the splitting treatment is performed in an assistance manner, thus the separation of the crystal silicon wafer and the EVA of the photovoltaic module 7 can be rapidly and effectively realized.

When the glass of the photovoltaic module 7 is positioned above the crystal silicon wafer, the pressure between the glass and the crystal silicon wafer is increased in the continuous temperature increasing process, the strength of the glass on the surface of the photovoltaic module 7 is high, so the crystal silicon wafer is easily damaged; after the photovoltaic module 7 is overturned and in a case that the back plate is positioned above the crystal silicon wafer, if the back plate and the crystal silicon wafer are not separated through the cutting knife 82, the back plate will shrink during heating in the continuous temperature increasing process, a stress will be generated, and therefore the silicon wafer is broken. Accordingly, in the present application, the splitting apparatus is provided for assisting in splitting EVA, and isolating the glass from the crystal silicon wafer, as well as isolating the back plate from the crystal silicon wafer, and therefore, the pressure generated on the crystal silicon wafer due to large strength of the glass and shrinkage of the back plate is prevented; and the cutting knife 82 plays an effect of isolating and protecting the crystal silicon wafer, thus the integrity of the crystal silicon wafer can be ensured during the pyrolysis process, and the crystal silicon wafer with favorable integrity is obtained.

In the description of the present disclosure, it is to be understood that the orientation or position relationship indicated by the terms of “center”, “longitudinal”, “transverse”, “length”, “width”, “thickness”, “up”, “down”, “front”, “back”, “left”, “right”, “vertical”, “horizontal”, “top”, “bottom”, “inside”, “outside”, “clockwise”, “counterclockwise” and the like is the orientation or position relationship shown in the accompanying drawings, and it is only to facilitate the description of the present disclosure and simplify the description, rather than indicating or implying that the indicated devices or components must have a specific orientation, be constructed or operated in a specific orientation, so it cannot be understood as a limitation of the present disclosure.

In addition, the terms “first” and “second” are for descriptive purposes only, and cannot be understood as indicating or implying relative importance or implicitly indicating the number of indicated technical characteristics. Therefore, the characteristic defined with the “first” and “second” may explicitly or implicitly include one or more such characteristics.

Unless otherwise expressly and specifically qualified, in the description of the present disclosure, the “plurality” means two or more than two.

The above description is only the better specific embodiments of the present disclosure, but the protection scope of the present disclosure is not limited to this, and the equivalent replacement or changes made by any person skilled in the art of the present disclosure within the scope of the technology disclosed in the present disclosure according to the technical solution and the inventive concept of the present disclosure should be covered by the protection scope of the present disclosure.

What is claimed is:

1. A pyrolysis apparatus for completely separating an ethylene-vinyl acetate copolymer (EVA) crystal silicon wafer from a waste photovoltaic module, comprising a heating mechanism controlled by a control system and mounted in a pyrolysis box and being capable of performing telescopic motion in a vertical direction;
an overturning assembly for fixedly clamping and driving the photovoltaic module to overturn, the overturning assembly being arranged just under the heating mechanism; and
a splitting assembly for separating the photovoltaic module, the splitting assembly being arranged at a left side of the photovoltaic module fixedly clamped by the overturning assembly, and a cutting knife of the splitting assembly and a middle part of an EVA of the photovoltaic module being on a same horizontal plane.

2. The pyrolysis apparatus according to claim 1, wherein the heating mechanism comprises a distribution box fixed in the pyrolysis box, a mounting frame fixed above the distribution box, an air inlet pipe fixed between the mounting frame and the distribution box, a hose fixedly connected to the air inlet pipe, a hot air pipe fixedly connected to the hose, and an air heater fixedly connected to an inlet end of the hot air pipe.

3. The pyrolysis apparatus according to claim 2, wherein two hydraulic push cylinders connected in series are fixed at an outer top of the pyrolysis box, and bottoms of the two hydraulic push cylinders extend and are fixed to the mounting frame; and
a laser sensor is fixed at one end of the mounting frame.

4. The pyrolysis apparatus according to claim 2, wherein a plurality of distribution holes are formed in a bottom of the distribution box, transversely arranged distribution holes and vertically arranged distribution holes are spaced at equal intervals, and nozzles are fixed in the plurality of distribution holes through threads.

5. The pyrolysis apparatus according to claim 1, wherein the overturning assembly comprises a left clamping plate and a right clamping plate for clamping the photovoltaic assembly, an electric push rod fixedly connected to the right clamping plate, and an overturning motor fixedly connected to the left clamping plate; and
wherein the overturning motor is fixed outside the pyrolysis box; and a left fixed pad and a right fixed pad are correspondingly fixed to a side wall of the left clamping plate and a side wall of the right clamping plate, wherein the side wall of the left clamping plate and the side wall of the right clamping plate are adjacent to each other.

6. The pyrolysis apparatus according to claim 5, wherein the electric push rod is fixed to a push rod seat, and the electric push rod is further fixed to an inner ring of a bearing; the bearing is fixed in a mounting hole formed in the pyrolysis box; and
wherein a displacement sensor is fixed at a front end of the push rod seat; and a detection probe of the displacement sensor is inserted into the right clamping plate.

7. The pyrolysis apparatus according to claim 1, wherein the splitting assembly comprises a cutting knife inserted into a limiting frame, a fixed knife rest fixedly connected to one end of the cutting knife, a fixed sleeve fixedly connected to one end of the fixed knife rest, a nut pair mounted in the fixed sleeve, and a ball screw driven by a screw motor to drive the nut pair to perform linear motion; one end of the ball screw is fixed to a fixed block; and a first end of the fixed block is connected to the limiting frame, and a second end of the fixed block is fixed to an inner wall of the pyrolysis box.

8. The pyrolysis apparatus according to claim 1, wherein the control system is electrically connected to a power supply module, an intelligent temperature controller is arranged in the control system, and the intelligent temperature controller is electrically connected to an air heater; and
the control system is further electrically connected to a screw motor, an overturning motor, an electric push rod and hydraulic push cylinders, and signals detected by a laser sensor and a displacement sensor are transmitted to the control system.
